(19) United States
(12) Patent Application Publication
(10) Pub. No.: US 2026/0231452 A1
(43) Pub. Date: Aug. 6, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yoko IWAKAJI, Meguro Tokyo (JP); Kenichi MATSUSHITA, Nonoichi Ishikawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/241,483

(22) Filed: Jun. 18, 2025

(30) Foreign Application Priority Data
Feb. 6, 2025 (JP) 2025-018619

(51) Int. Cl. H10D 12/00; H10D 8/20; H10D 62/10; H10D 62/60; H10D 64/00

(52) U.S. Cl. CPC H10D 12/415; H10D 8/20; H10D 12/481; H10D 62/108; H10D 62/124; H10D 62/60; H10D 64/112

(57) ABSTRACT

A semiconductor part includes a first semiconductor layer, a second semiconductor layer positioned between a first electrode and the first semiconductor layer in at least an active region, a third semiconductor layer positioned between the first electrode and the first semiconductor layer, a fourth semiconductor layer positioned between a second electrode and the first semiconductor layer in the active region, and a fifth semiconductor layer positioned between the second electrode and the first semiconductor layer in a termination region, the fifth semiconductor layer being positioned between the fourth semiconductor layer and a side surface. The third semiconductor layer includes a first part positioned in the active region, the first part facing at least a part of the fifth semiconductor layer, and a second part positioned between the first part and the side surface. The second part is thinner than the first part.

### CROSS-REFERENCE TO RELATED APPLICATION

This application is based upon and claims the benefit of priority from Japanese Patent Application No. 2025-018619, filed on Feb. 6, 2025; the entire contents of which are incorporated herein by reference.

### FIELD

Embodiments described herein relate generally to a semiconductor device.

### BACKGROUND

IGBTs (Insulated Gate Bipolar Transistors) and diodes are widely used as semiconductor devices for power control. A configuration is known in which current and voltage oscillations at turn-off are reduced by including a buffer layer between the collector layer (or the cathode layer) and the base layer.

### BRIEF DESCRIPTION OF THE DRAWINGS

FIG. 1 is a schematic plan view of a semiconductor device of a first embodiment;

FIG. 2 is an A-A cross-sectional view of FIG. 1;

FIG. 3 is a schematic cross-sectional view of a semiconductor device of a second embodiment;

FIG. 4 is a schematic cross-sectional view of a semiconductor device of a third embodiment;

FIG. 5 is a schematic cross-sectional view of a semiconductor device of a fourth embodiment;

FIG. 6 is a schematic cross-sectional view of a semiconductor device of a fifth embodiment;

FIG. 7 is a schematic cross-sectional view of a semiconductor device of a sixth embodiment;

FIG. 8 is a schematic cross-sectional view of a semiconductor device of a seventh embodiment;

FIG. 9 is a schematic cross-sectional view of a semiconductor device of an eighth embodiment;

FIG. 10 is a schematic cross-sectional view of a semiconductor device of a nineth embodiment;

FIG. 11 is a schematic cross-sectional view of a semiconductor device of a tenth embodiment;

FIG. 12 is a schematic cross-sectional view of a semiconductor device of an eleventh embodiment; and

FIG. 13 is a graph showing I-V characteristic simulation results.

### DETAILED DESCRIPTION

According to one embodiment, a semiconductor device includes a first electrode; a second electrode; and a semiconductor part positioned between the first electrode and the second electrode in a first direction, the semiconductor part including an active region, a side surface, and a termination region positioned between the active region and the side surface in a direction crossing the first direction, the semiconductor part including a first semiconductor layer of a first conductivity type, a second semiconductor layer positioned between the first electrode and the first semiconductor layer in the first direction in at least the active region, the second semiconductor layer being electrically connected with the first electrode, a third semiconductor layer positioned between the first electrode and the first semiconductor layer in the first direction, the third semiconductor layer being of the first conductivity type and having a higher first-conductivity-type impurity concentration than the first semiconductor layer, a fourth semiconductor layer positioned between the second electrode and the first semiconductor layer in the first direction in the active region, the fourth semiconductor layer being electrically connected with the second electrode, the fourth semiconductor layer being of a second conductivity type, and a fifth semiconductor layer positioned between the second electrode and the first semiconductor layer in the first direction in the termination region, the fifth semiconductor layer being positioned between the fourth semiconductor layer and the side surface in the direction crossing the first direction, the fifth semiconductor layer being of the second conductivity type, the third semiconductor layer including a first part positioned in the active region, the first part facing at least a part of the fifth semiconductor layer in the first direction, and a second part positioned between the first part and the side surface in the direction crossing the first direction, the second part being thinner than the first part.

Exemplary embodiments will now be described with reference to the drawings. Similar components in the drawings are marked with like reference numerals. In the drawings, a direction along a Z-axis is referred to as a first direction Z; a direction along an X-axis is referred to as a second direction X; and a direction along a Y-axis is referred to as a third direction Y. The second direction X and the third direction Y are directions that cross the first direction Z. According to the embodiment, for example, the first direction Z, the second direction X, and the third direction Y are orthogonal to each other. In the description of the specification, for example, the arrow direction of the Z-axis may be referred to as relatively up or above; and the opposite direction of the arrow of the Z-axis may be referred to as relatively down or below.

In the specification, the thickness of each component represents the maximum value of the thickness in the first direction Z. In the specification, the distance in a specific direction between components represents the shortest distance in the specific direction.

### First Embodiment

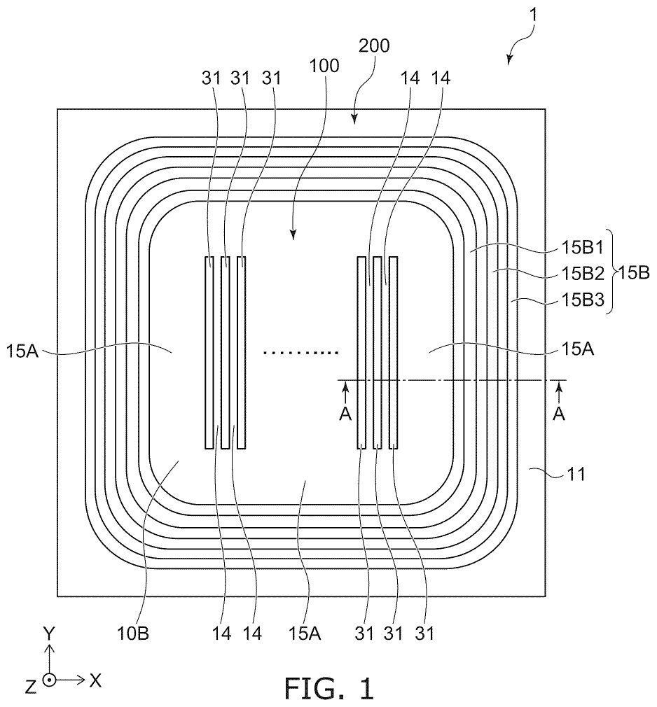

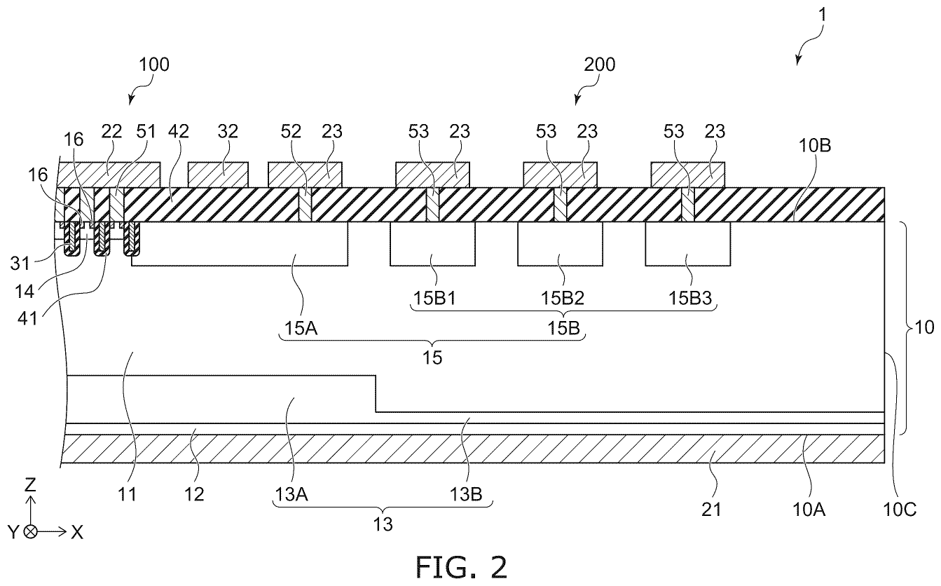

A semiconductor device 1 according to a first embodiment will now be described with reference to FIGS. 1 and 2.

The semiconductor device 1 includes a first electrode 21, a second electrode 22, a gate electrode 31, a gate insulating film 41, an insulating layer 42, and a semiconductor part 10.

As shown in FIG. 2, the semiconductor part 10 is positioned between the first electrode 21 and the second electrode 22 in the first direction Z. The semiconductor part 10 includes a first surface 10A, a second surface 10B positioned at the side opposite to the first surface 10A in the first direction Z, and a side surface 10C. The first electrode 21 is located at the first surface 10A. The second electrode 22 is positioned above the second surface 10B.

FIG. 1 is a schematic plan view of the second surface 10B of the semiconductor part 10. FIG. 2 is an A-A cross-sectional view of FIG. 1. The configurations on the second surface 10B of the semiconductor part 10 are not illustrated in FIG. 1.

The semiconductor part 10 includes an active region 100 and a termination region 200. The termination region 200 is positioned between the active region 100 and the side surface 10C of the semiconductor part 10 in the second and third directions X and Y. For example, the termination region 200 surrounds the active region 100 when viewed in plan.

For example, silicon can be used as the material of the semiconductor part 10. Or, for example, silicon carbide, gallium nitride, etc., may be used as the material of the semiconductor part 10. Although a first conductivity type is described as an n-type and a second conductivity type is described as a p-type in the semiconductor part 10 according to the embodiment, the first conductivity type may be the p-type; and the second conductivity type may be the n-type.

The semiconductor part 10 includes an n-type first semiconductor layer 11, a p-type second semiconductor layer 12, an n-type third semiconductor layer 13, a p-type fourth semiconductor layer 14, a p-type fifth semiconductor layer 15, and an n-type sixth semiconductor layer 16.

The semiconductor device 1 according to the first embodiment has, for example, an IGBT (Insulated Gate Bipolar Transistor) structure. The semiconductor device 1 is, for example, Reverse-Conducting IGBT (RC-IGBT). In the IGBT, the first electrode 21 functions as a collector electrode; the second electrode 22 functions as an emitter electrode; the first semiconductor layer 11 functions as an n-type base layer (or a drift layer); the second semiconductor layer 12 functions as a p-type collector layer; the third semiconductor layer 13 functions as an n-type buffer layer; the fourth semiconductor layer 14 functions as a p-type base layer; and the sixth semiconductor layer 16 functions as an n-type emitter layer.

The second semiconductor layer 12 is positioned between the first electrode 21 and the first semiconductor layer 11 in the first direction Z in at least the active region 100. According to the embodiment, the second semiconductor layer 12 also is positioned between the first electrode 21 and the termination region 200 and is continuous between the active region 100 and the termination region 200. The second semiconductor layer 12 contacts the first electrode 21 and is electrically connected with the first electrode 21.

The third semiconductor layer 13 is positioned between the first electrode 21 and the first semiconductor layer 11 in the first direction Z. The third semiconductor layer 13 is continuous in the active region 100 and the termination region 200. The n-type impurity concentration of the third semiconductor layer 13 is greater than the n-type impurity concentration of the first semiconductor layer 11.

The fourth semiconductor layer 14 is positioned between the second electrode 22 and the first semiconductor layer 11 of the active region 100 in the first direction Z, and is electrically connected with the second electrode 22.

The fifth semiconductor layer 15 is positioned between the second electrode 22 and the first semiconductor layer 11 in the first direction Z in the termination region 200, and is positioned between the fourth semiconductor layer 14 and the side surface 10C of the semiconductor part 10 in the second and third directions X and Y.

The sixth semiconductor layer 16 is positioned on the fourth semiconductor layer 14 in the active region 100 and is electrically connected with the second electrode 22.

The insulating layer 42 is located on the second surface 10B of the semiconductor part 10. The second electrode 22 is located on the second surface 10B of the semiconductor part 10 with the insulating layer 42 interposed. In the active region 100, the second electrode 22 and the sixth semiconductor layer 16 are electrically connected by a first connecting part 51 extending through the insulating layer 42 in the first direction Z. The first connecting part 51 also electrically connects the second electrode 22 and the fourth semiconductor layer 14 in the active region 100.

As shown in FIG. 2, the gate electrode 31 extends downward from the second surface 10B of the semiconductor part 10 and is positioned in the semiconductor part 10. The lower end of the gate electrode 31 is positioned in the first semiconductor layer 11 to be lower than the p-n junction between the fourth semiconductor layer 14 and the first semiconductor layer 11. For example, conductive polycrystalline silicon can be used as the material of the gate electrode 31.

The gate insulating film 41 is located between the gate electrode 31 and the semiconductor part 10. The side surface of the gate electrode 31 faces the fourth semiconductor layer 14 via the gate insulating film 41. The insulating layer 42 is located between the gate electrode 31 and the second electrode 22.

Multiple gate electrodes 31 are located in the active region 100. As shown in FIG. 1, the multiple gate electrodes 31 are separated from each other in the second direction X; and each gate electrode 31 extends in the third direction Y.

As shown in FIG. 2, the semiconductor device 1 further includes a gate wiring part 32 located on the insulating layer 42 in the termination region 200. The gate electrode 31 is electrically connected with the gate wiring part 32 via a not-illustrated connecting part extending through the insulating layer 42.

In the specification, the region in which the fourth semiconductor layer 14, the sixth semiconductor layer 16, and the gate electrode 31 are located is referred to as the active region 100. The active region 100 is a region in which the current (the collector current) flowing in the first direction Z through the semiconductor part 10 can be switched on and off by the voltage of the gate electrode 31.

For example, a positive potential is applied to the first electrode 21; and a ground potential is applied to the second electrode 22. When a potential greater than a prescribed threshold (a potential higher than the potential of the second electrode 22 (the emitter electrode)) is applied to the gate electrode 31, an inversion layer (an n-type channel) is formed in the region of the fourth semiconductor layer 14 (the p-type base layer) facing the gate electrode 31; and electrons are injected from the second electrode 22 into the first semiconductor layer 11 (the n-type base layer) via the sixth semiconductor layer 16 (the n-type emitter layer) and the n-type channel. Therefore, the second semiconductor layer 12 (the p-type collector layer) is biased to be positive with respect to the first semiconductor layer 11; holes are injected from the second semiconductor layer 12 into the first semiconductor layer 11; and the semiconductor device 1 is switched to an on-state. The holes that are injected into the first semiconductor layer 11 flow from the first semiconductor layer 11 into the fourth semiconductor layer 14. When a potential that is less than the threshold is applied to the gate electrode 31, the n-type channel disappears, and the semiconductor device 1 is switched to an off-state.

In recent years, to reduce the steady loss and switching loss of IGBTs, the first semiconductor layer 11 (the n-type base layer) is being made thinner, which undesirably causes oscillations of the collector current and the collector-emitter voltage at turn-off. By providing the third semiconductor layer 13 (the n-type buffer layer), which has a higher n-type impurity concentration than the first semiconductor layer 11, between the second semiconductor layer 12 (the p-type collector layer) and the first semiconductor layer 11 (the n-type base layer), the oscillations at turn-off can be reduced. There is a risk that making the third semiconductor layer 13 (the n-type buffer layer) thicker may result in a relatively thinner first semiconductor layer 11 (n-type base layer), and may reduce the breakdown voltage.

According to the embodiment, the third semiconductor layer 13 (the n-type buffer layer) includes a first part 13A and a second part 13B. The first part 13A is positioned in the active region 100 and faces at least a portion of the fifth semiconductor layer 15 in the first direction Z. The second part 13B is positioned between the first part 13A and the side surface 10C of the semiconductor part 10 in the second and third directions X and Y. The thickness of the second part 13B is less than the thickness of the first part 13A. The thickness of the first part 13A is, for example, not less than 5 μm. The thickness of the second part 13B is, for example, not less than 1 μm but less than 5 μm.

For example, the first part 13A and the second part 13B can be formed by separately implanting impurities through the first surface 10A side. The first part 13A and the second part 13B are not limited to being formed by separately implanting impurities. The impurity that is injected when forming the second part 13B may be included in the first part 13A. In other words, the process of forming the second part 13B may implant an impurity thinly over the entire surface of the first surface 10A. Subsequently, the first part 13A can be formed by selectively implanting the impurity through the first surface 10A.

According to the embodiment, a thin n-type buffer layer (the second part 13B) is located in the termination region 200 while reducing oscillations at turn-off by including a thick n-type buffer layer (the first part 13A) in the active region 100, and so breakdown voltage reduction occurs less easily than when a thick n-type buffer layer (the first part 13A) is provided over the entire termination region 200 (the region up to the side surface 10C).

According to the embodiment, the fifth semiconductor layer 15 includes an inner part 15A that faces the first part 13A of the third semiconductor layer 13 in the first direction, and a fifth part 15B separated from the inner part 15A at the side surface 10C side in the second and third directions X and Y. When viewed in plan as shown in FIG. 1, the inner part 15A continuously surrounds the active region 100; and the fifth part 15B continuously surrounds the inner part 15A.

The fifth part 15B does not contact the side surface 10C of the semiconductor part 10. The fifth part 15B functions as a p-type guard ring layer and increases the breakdown voltage by making it easier for the depletion layer to spread in the termination region 200 in the off-state.

As multiple p-type guard ring layers, for example, the fifth part 15B includes a first outer part 15B1, a second outer part 15B2, and a third outer part 15B3. The first outer part 15B1 is positioned between the inner part 15A and the second outer part 15B2 in the second and third directions X and Y. The second outer part 15B2 is positioned between the first outer part 15B1 and the third outer part 15B3 in the second and third directions X and Y. The third outer part 15B3 is positioned between the second outer part 15B2 and the side surface 10C in the second and third directions X and Y. The number of multiple p-type guard ring layers may be one, four, or more. A p-type guard ring layer may not be included.

The depth from the second surface 10B of the inner part 15A is greater than the depth from the second surface 10B of the fourth semiconductor layer 14 (the p-type base layer) of the active region 100. The inner part 15A performs the role of separating the fifth part 15B (the p-type guard ring layer), which is a guard ring, from the active region 100 by not less than a prescribed distance. The width in the second direction X of the inner part 15A is greater than the widths in the second direction X of the outer parts 15B1, 15B2, and 15B3 of the fifth part 15B. In FIG. 1, the widths in the third direction Y of the inner part 15A positioned in the positive and negative directions in the third direction Y from the gate electrodes 31 extending in the third direction Y are greater than the widths in the third direction Y of the outer parts 15B1, 15B2, and 15B3 of the fifth part 15B. The distance in the second direction X and the distance in the third direction Y between the first outer part 15B1 and the gate electrode 31 positioned most proximate to the termination region 200 each are, for example, not less than 100 μm.

A field plate 23 may be located on the insulating layer 42 of the termination region 200 as a termination breakdown voltage structure. The potential of the field plate 23 is, for example, floating. The portion of the inner part 15A at the fifth part 15B side is electrically connected with the field plate 23 by a second connecting part 52 extending through the insulating layer 42. The first outer part 15B1, the second outer part 15B2, and the third outer part 15B3 are electrically connected with the field plates 23 by third connecting parts 53 extending through the insulating layer 42.

According to the embodiment, for example, the boundary between the first part 13A and the second part 13B of the third semiconductor layer 13 (the n-type buffer layer) is positioned between the inner part 15A and the first outer part 15B1 of the fifth semiconductor layer 15. The boundary between the first part 13A and the second part 13B of the third semiconductor layer 13 (the n-type buffer layer) may face the inner part 15A or the first outer part 15B1 in the first direction Z. In order to suppress a reduction of the breakdown voltage and easily control the position at which avalanche breakdown occurs when a high voltage is applied between the emitter and the collector to be at the bottom of a portion of the inner part 15A separated from the active region 100, it is desirable to position the boundary between the first part 13A and the second part 13B between the inner part 15A and the first outer part 15B1 of the fifth semiconductor layer 15. The inner part 15A faces the first part 13A of the third semiconductor layer 13 in the first direction Z. The fifth part 15B faces the second part 13B of the third semiconductor layer 13 in the first direction Z.

According to the embodiment, the distance in the first direction Z between the first part 13A of the third semiconductor layer 13 and the inner part 15A of the fifth semiconductor layer 15 of the termination region 200 is less than the distance in the first direction Z between the first part 13A of the third semiconductor layer 13 and the fourth semiconductor layer 14 of the active region 100. The thickness of the first semiconductor layer 11 between the inner part 15A of the fifth semiconductor layer 15 and the first part 13A of the third semiconductor layer 13 is less than the thickness of the first semiconductor layer 11 between the fourth semiconductor layer 14 and the first part 13A of the third semiconductor layer 13. Therefore, the position at which avalanche breakdown occurs is easily controlled to be not in the active region 100, but at the bottom of the inner part 15A in the termination region 200. To increase the reliability of the semiconductor device, it is desirable for the position at which avalanche breakdown occurs to be distant to the active region 100.

The avalanche current flows more easily between the inner part 15A of the fifth semiconductor layer 15 and the first part 13A of the third semiconductor layer 13, but an electric field increase at the first surface 10A can be suppressed by the first part 13A, which is a thick n-type buffer layer; and the avalanche current can be prevented from increasing further. As a result, in the I-V characteristic, the voltage at which the I-V characteristic switches to a negative resistance region can be increased, and the element breakdown tolerance can be improved. The I-V characteristic is illustrated by a graph in which the horizontal axis is the voltage, and the vertical axis is the current. In other words, avalanche breakdown occurs more easily at the inner part 15A of the fifth semiconductor layer 15, but the current value and the voltage value at which further avalanche breakdown occurs at the first part 13A of the third semiconductor layer 13 can be increased. By suppressing the avalanche breakdown at the first part 13A of the third semiconductor layer 13, the switching to the negative resistance region can be suppressed. The tolerance to avalanche breakdown can be increased.

Other embodiments will now be described; and mainly configurations that are different from those of the first embodiment above are described.

### Second Embodiment

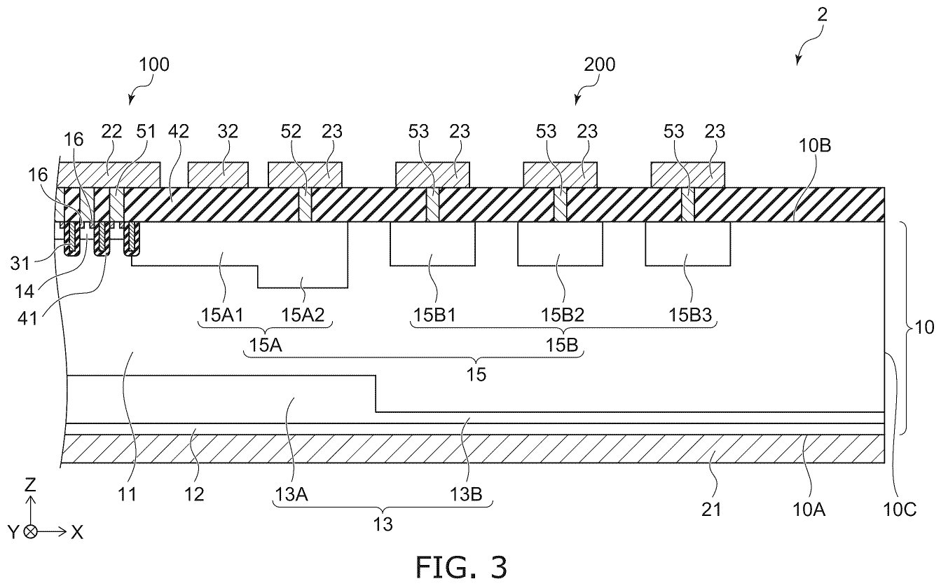

In the semiconductor device 2 according to the second embodiment as shown in FIG. 3, the inner part 15A of the fifth semiconductor layer 15 includes a third part 15A1 and a fourth part 15A2.

The third part 15A1 is positioned between the active region 100 and the fourth part 15A2 in the second and third directions X and Y. The third part 15A1 faces the first part 13A of the third semiconductor layer 13 in the first direction Z.

The fourth part 15A2 is positioned between the third part 15A1 and the fifth part 15B in the second and third directions X and Y and is adjacent to the third part 15A1. The fourth part 15A2 faces the first part 13A of the third semiconductor layer 13 in the first direction Z.

The depth of the fourth part 15A2 is greater than the depth of the third part 15A1 with reference to the second surface 10B of the semiconductor part 10. The distance in the first direction Z between the fourth part 15A2 and the first part 13A of the third semiconductor layer 13 is less than the distance in the first direction Z between the third part 15A1 and the first part 13A of the third semiconductor layer 13. Therefore, the position at which avalanche breakdown occurs is easily controlled to be at the bottom of the fourth part 15A2 that is separated further from the active region 100 than the third part 15A1. The avalanche current flows more easily between the fourth part 15A2 and the first part 13A of the third semiconductor layer, but electric field concentration can be relaxed, and the avalanche current can be prevented from increasing further. As a result, the voltage at which the I-V characteristic switches to the negative resistance region can be increased, and the breakdown tolerance can be improved.

The fifth part 15B is separated from the fourth part 15A2 toward the side surface 10C side of the semiconductor part 10 in the second and third directions X and Y. The distance in the first direction Z between the fourth part 15A2 and the first part 13A of the third semiconductor layer 13 is less than the distance in the first direction Z between the fifth part 15B and the second part 13B of the third semiconductor layer 13.

According to the second embodiment, the distance in the first direction Z between the third part 15A1 and the first part 13A of the third semiconductor layer 13 is less than the distance in the first direction Z between the first part 13A of the third semiconductor layer 13 and the fourth semiconductor layer 14 of the active region 100.

### Third Embodiment

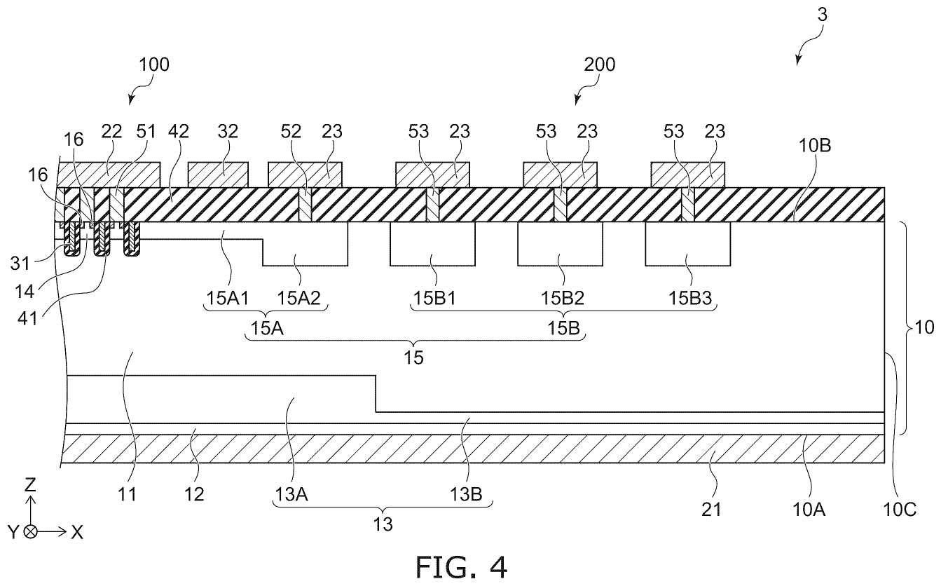

As in a semiconductor device 3 according to a third embodiment shown in FIG. 4, the distance in the first direction Z between the third part 15A1 and the first part 13A of the third semiconductor layer 13 may be equal to the distance in the first direction Z between the first part 13A of the third semiconductor layer 13 and the fourth semiconductor layer 14 of the active region 100.

According to the third embodiment, with respect to the second surface 10B of the semiconductor part 10, the depth of the fourth semiconductor layer 14 and the depth of the third part 15A1 are the same, and the depth of the fourth part 15A2 and the depth of the fifth part 15B are the same. As a result, for example, it is easier to form the fourth semiconductor layer 14 and the fifth semiconductor layer 15 by ion implantation of a p-type impurity. For example, a first ion implantation may be performed in the region of the semiconductor part 10 at the second surface 10B side to form the fourth semiconductor layer 14 and the fifth semiconductor layer 15, and then the region in which the fourth semiconductor layer 14 and the third part 15A1 of the fifth semiconductor layer 15 are formed is covered with a resist mask; and a second ion implantation is performed in the region in which the fourth part 15A2 of the fifth semiconductor layer 15 and the fifth part 15B are formed.

### Fourth Embodiment

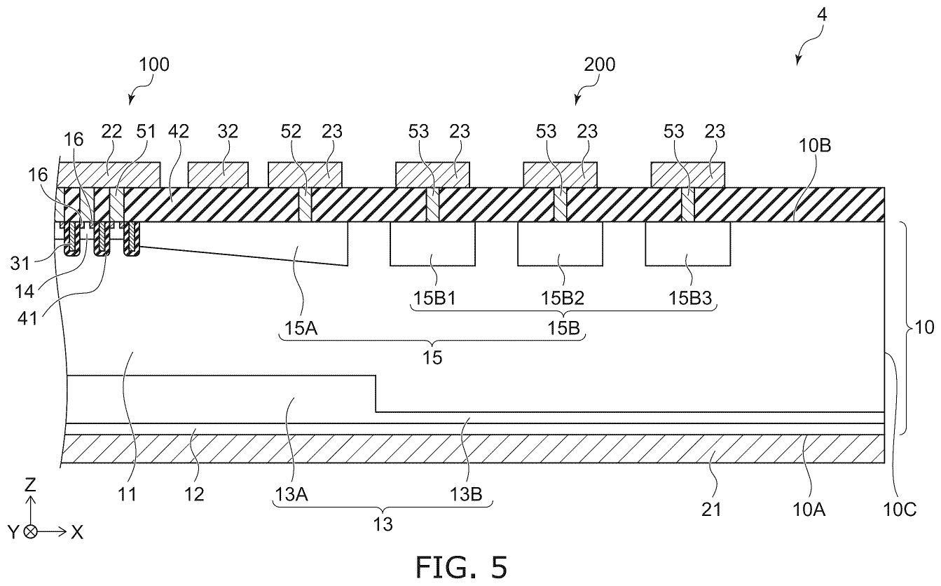

In a semiconductor device 4 according to a fourth embodiment shown in FIG. 5, the distance in the first direction Z between the inner part 15A of the fifth semiconductor layer 15 and the first part 13A of the third semiconductor layer 13 gradually decreases in the second and third directions X and Y from the active region 100 side toward the side surface 10C of the semiconductor part 10. According to the embodiment as well, the position at which avalanche breakdown occurs can be easily controlled to be at the bottom of the portion of the inner part 15A more distant to the active region 100.

The depth of the inner part 15A of the fifth semiconductor layer 15 with reference to the second surface 10B of the semiconductor part 10 gradually increases in the second and third directions X and Y from the active region 100 side toward the side surface 10C of the semiconductor part 10. For example, the inner part 15A of the fourth embodiment can be formed by setting the spacing of the openings formed in the resist film for the ion implantation to form the inner part 15A to be relatively small at the active region 100 side and to relatively increase toward the fifth part 15B side.

### Fifth Embodiment

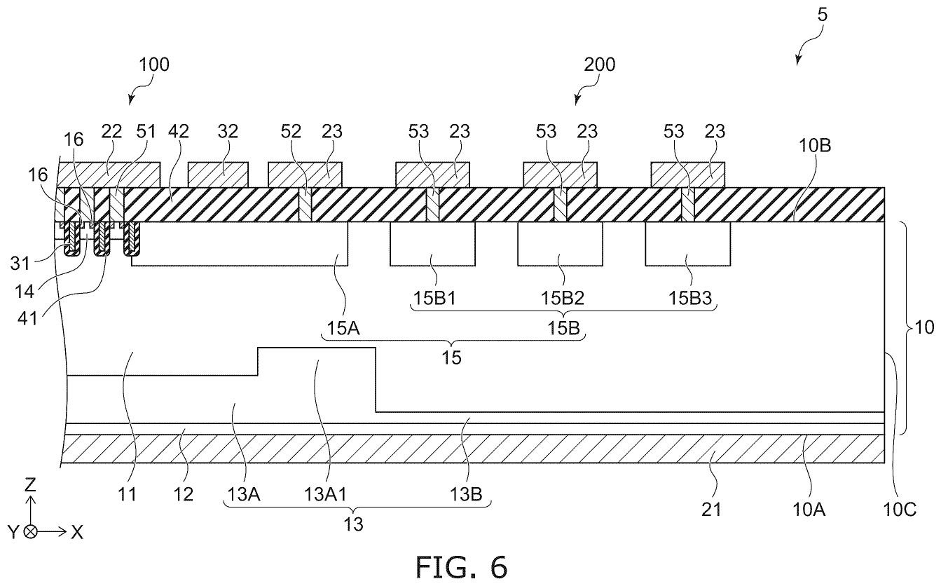

In a semiconductor device 5 according to a fifth embodiment shown in FIG. 6, an end portion 13A1 of the first part 13A of the third semiconductor layer 13 at the second part 13B side has a greater thickness in the first direction Z than the portion of the first part 13A at the active region 100 side. The distance in the first direction Z between the inner part 15A of the fifth semiconductor layer 15 and the first part 13A of the third semiconductor layer 13 is small at the end portion 13A1 distant to the active region 100; and the position at which avalanche breakdown occurs can be easily controlled to be at the bottom of the portion of the inner part 15A distant to the active region 100.

### Sixth Embodiment

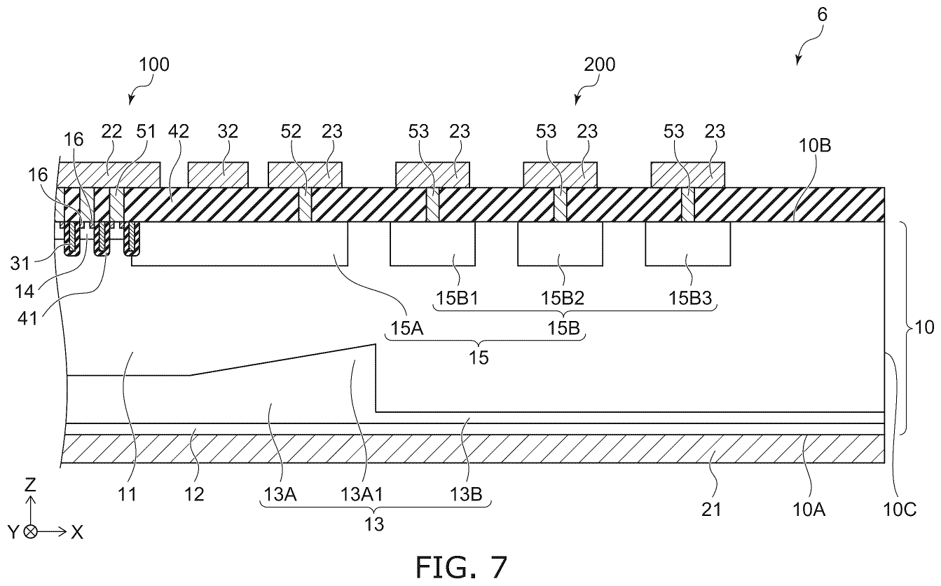

In a semiconductor device 6 according to a sixth embodiment shown in FIG. 7, the thickness in the first direction Z of the end portion 13A1 of the first part 13A of the third semiconductor layer 13 at the second part 13B side gradually increases from the active region 100 side toward the side surface 10C of the semiconductor part 10. The distance in the first direction Z between the inner part 15A of the fifth semiconductor layer 15 and the first part 13A of the third semiconductor layer 13 gradually decreases away from the active region 100; and the position at which avalanche breakdown occurs can be easily controlled to be at the bottom of the portion of the inner part 15A distant to the active region 100.

### Seventh Embodiment

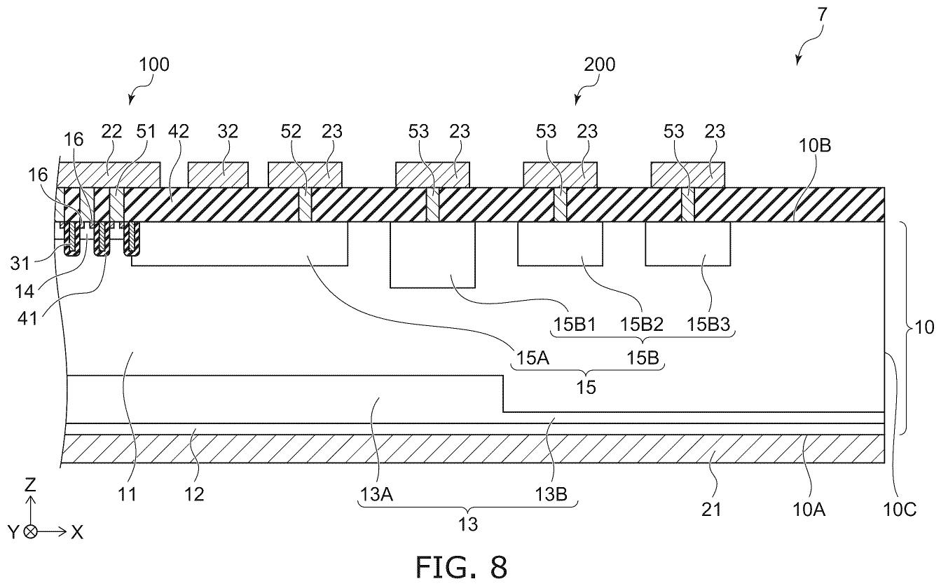

In a semiconductor device 7 according to a seventh embodiment shown in FIG. 8, the depth of the first outer part 15B1 of the fifth semiconductor layer 15 is greater than the depth of the inner part 15A, the depth of the second outer part 15B2, and the depth of the third outer part 15B3 with respect to the second surface 10B of the semiconductor part 10. The first part 13A of the third semiconductor layer 13 extends under the first outer part 15B1 from the active region 100 in the second and third directions X and Y. The first outer part 15B1 faces the first part 13A of the third semiconductor layer 13 in the first direction Z.

The distance in the first direction Z between the first outer part 15B1 and the first part 13A of the third semiconductor layer 13 is less than the distance in the first direction Z between the inner part 15A and the first part 13A of the third semiconductor layer 13. As a result, the position at which avalanche breakdown occurs can be easily controlled to be at the bottom of the first outer part 15B1 more distant to the active region 100 than the inner part 15A. The first part 13A of the third semiconductor layer 13 may extend to a position facing the second outer part 15B2 or a position facing the third outer part 15B3. In the semiconductor device 7 according to the embodiment, the boundary between the first part 13A and the second part 13B of the third semiconductor layer 13 (the n-type buffer layer) is positioned between the first outer part 15B1 and the second outer part 15B2 of the fifth semiconductor layer 15. The boundary between the first part 13A and the second part 13B of the third semiconductor layer 13 (the n-type buffer layer) may face the first outer part 15B1 or the second outer part 15B2 in the first direction Z. In order to suppress the reduction of the breakdown voltage and easily control the position at which avalanche breakdown occurs to be at the bottom of the part of the first outer part 15B1 distant to the active region 100, it is desirable to position the boundary between the first outer part 15B1 and the second outer part 15B2 of the fifth semiconductor layer 15.

### Eighth Embodiment

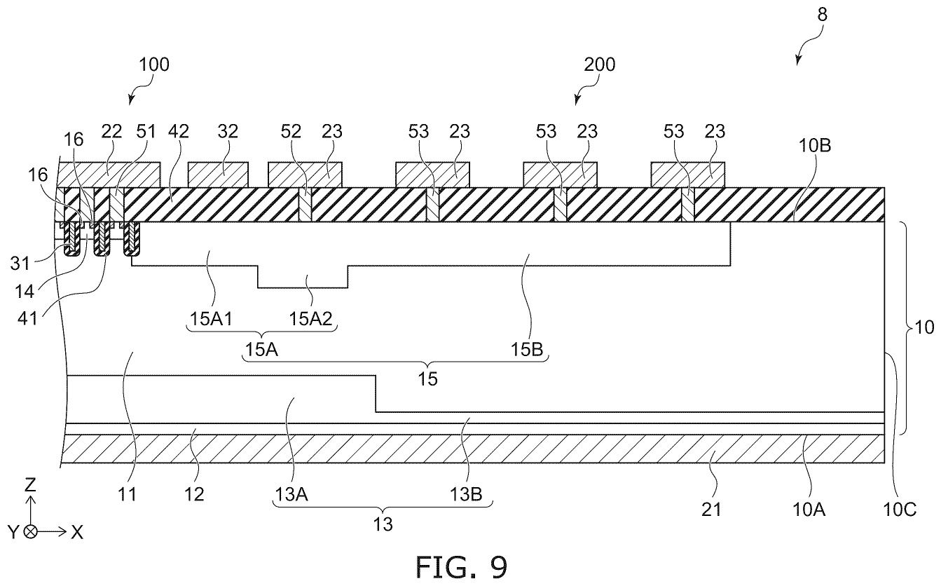

In the fifth semiconductor layer 15 of a semiconductor device 8 according to an eighth embodiment shown in FIG. 9, the inner part 15A and the fifth part 15B are continuous in the second and third directions X and Y. The depth of the fourth part 15A2 of the inner part 15A is greater than the depth of the third part 15A1 of the inner part 15A and the depth of the fifth part 15B with respect to the second surface 10B of the semiconductor part 10. The distance in the first direction Z to the third semiconductor layer 13 is smallest at the fourth part 15A2.

In the semiconductor device 8 according to the embodiment, the boundary between the first part 13A and the second part 13B of the third semiconductor layer 13 (the n-type buffer layer) is positioned further outward than the fourth part 15A2 of the inner part 15A and faces the fifth part 15B in the first direction Z. The boundary between the first part 13A and the second part 13B of the third semiconductor layer 13 (the n-type buffer layer) may face the fourth part 15A2 of the inner part 15A in the first direction Z. In order to suppress the reduction of the breakdown voltage and easily control the position at which avalanche breakdown occurs to be at the bottom of the portion of the fourth part 15A2 of the inner part 15A distant to the active region 100, it is desirable to position the boundary between the first part 13A and the second part 13B to face the fifth part 15B in the first direction Z further outward than the fourth part 15A2 of the inner part 15A.

In the semiconductor device 8 according to the eighth embodiment, the depth may gradually decrease from the fourth part 15A2 toward the end portion of the third part 15A1 at the active region 100 side, or may gradually decrease from the fourth part 15A2 toward the end portion of the fifth part 15B at the side surface 10C side.

### Ninth Embodiment

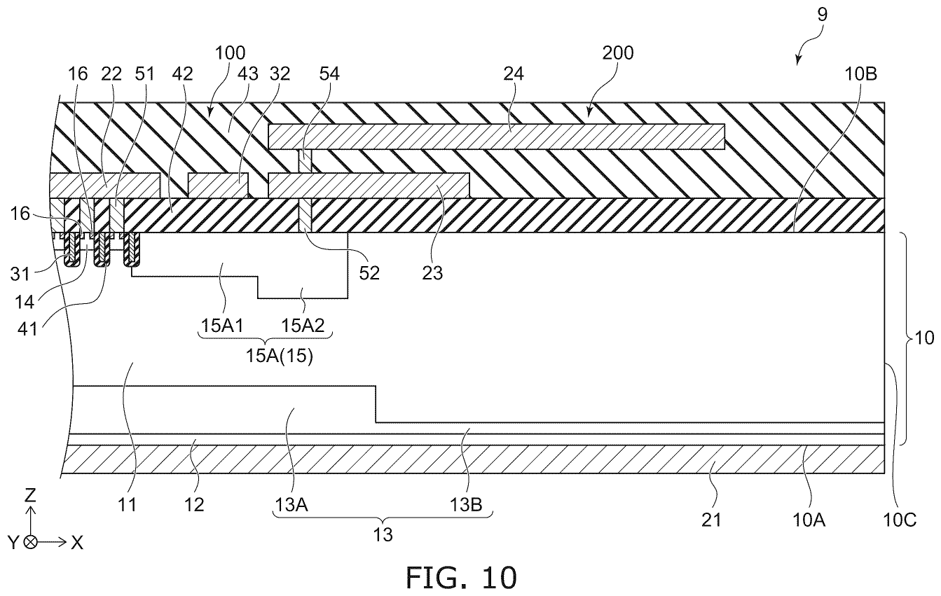

In a semiconductor device 9 according to a ninth embodiment shown in FIG. 10, as a termination breakdown voltage structure, a fifth part that is a p-type guard ring layer is not included in the semiconductor part 10; and the field plate 23 (a first field plate) and a field plate 24 (a second field plate) are located above the second surface 10B of the semiconductor part 10.

An insulating layer 43 (a second insulating layer) is located on the insulating layer 42 (a first insulating layer) to cover the second electrode 22, the gate wiring part 32, and the field plate 23. The field plate 24 is positioned in the insulating layer 43 and is electrically connected with the field plate 23 by a fourth connecting part 54. The field plate 24 extends in the second and third directions X and Y further toward the side surface 10C side of the semiconductor part 10 than the field plate 23.

The fifth semiconductor layer 15 is positioned between the first semiconductor layer 11 and the field plate 23 in the first direction Z. The end of the field plate 23 proximate to the side surface 10C is positioned more proximate to the side surface 10C than the end of the fifth semiconductor layer 15 proximate to the side surface 10C. The end of the field plate 23 proximate to the side surface 10C is positioned more proximate to the side surface 10C than the boundary between the first part 13A and the second part 13B of the third semiconductor layer 13.

In the semiconductor device 9 according to the embodiment, the boundary between the first part 13A and the second part 13B of the third semiconductor layer 13 (the n-type buffer layer) is positioned further outward than the fourth part 15A2 of the inner part 15A of the fifth semiconductor layer 15. The boundary between the first part 13A and the second part 13B of the third semiconductor layer 13 (the n-type buffer layer) may face the fourth part 15A2 of the inner part 15A in the first direction Z. In order to easily control the position at which avalanche breakdown occurs to be at the bottom of the portion of the fourth part 15A2 of the inner part 15A distant to the active region 100, it is desirable to position the boundary between the first part 13A and the second part 13B further outward than the fourth part 15A2 of the inner part 15A. To suppress the breakdown voltage reduction, it is desirable to position the boundary between the first part 13A and the second part 13B to face the field plate 23 in the first direction Z.

### Tenth Embodiment

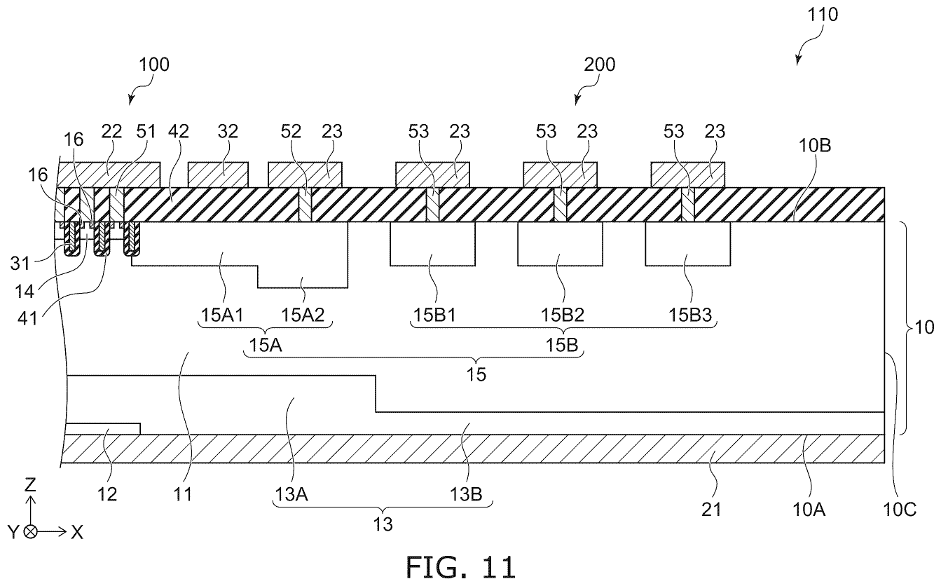

In a semiconductor device 110 according to a tenth embodiment shown in FIG. 11, the second semiconductor layer 12, which is the collector layer, is located in the active region 100, but is not included in the termination region 200. The third semiconductor layer 13 contacts the first electrode 21 in the termination region 200. The second semiconductor layer 12 may be of the n-type and may function as a cathode layer of the diode.

The field plate 23 includes a first region positioned above the fourth part 15A2 of the fifth semiconductor layer 15, and a second region positioned above the fifth part 15B of the fifth semiconductor layer 15. The first region and the second region are separated from each other in the second and third directions X and Y.

### Eleventh Embodiment

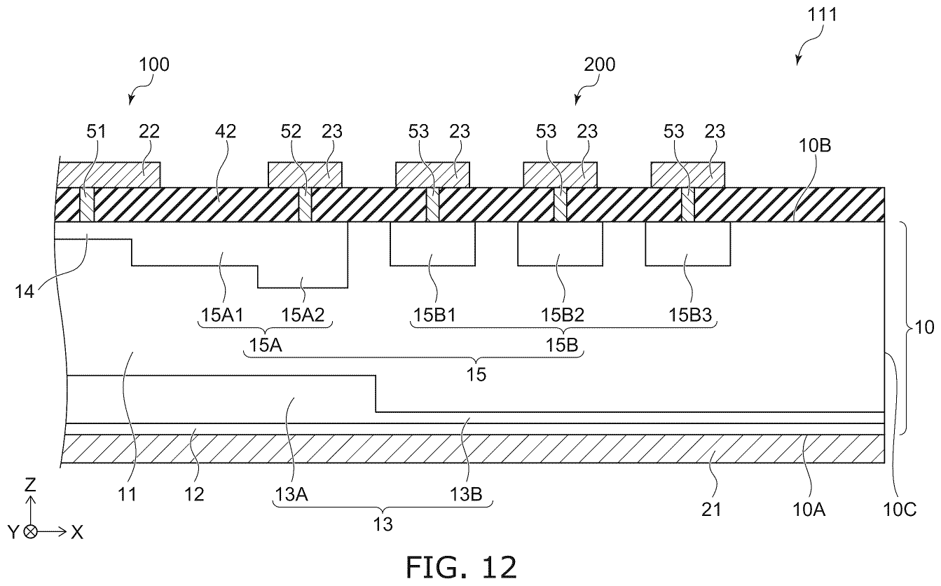

A semiconductor device 111 according to an eleventh embodiment shown in FIG. 12 is a diode. The second semiconductor layer 12 is of the n-type and functions as a cathode layer of the diode. The n-type impurity concentration of the second semiconductor layer 12 is greater than the n-type impurity concentration of the first semiconductor layer 11. The active region 100 does not include the sixth semiconductor layer (an emitter layer), a gate electrode, or a gate insulating film. The p-type fourth semiconductor layer 14 located on the first semiconductor layer 11 of the active region 100 functions as an anode layer of the diode. The first electrode 21 functions as a cathode electrode; and the second electrode 22 functions as an anode electrode.

A configuration similar to that of the IGBT described above is applicable as the configuration of the termination region 200 of the semiconductor device 111 (the diode) according to the eleventh embodiment.

A configuration similar to that of the IGBT described above is applicable as the configuration of the active region 100 of the semiconductor device 111 according to the eleventh embodiment. In this case, the semiconductor device 111 is, for example, RC-IGBT.

Two or more of the embodiments above may be appropriately combined within the extent of technical feasibility.

### Simulation Results

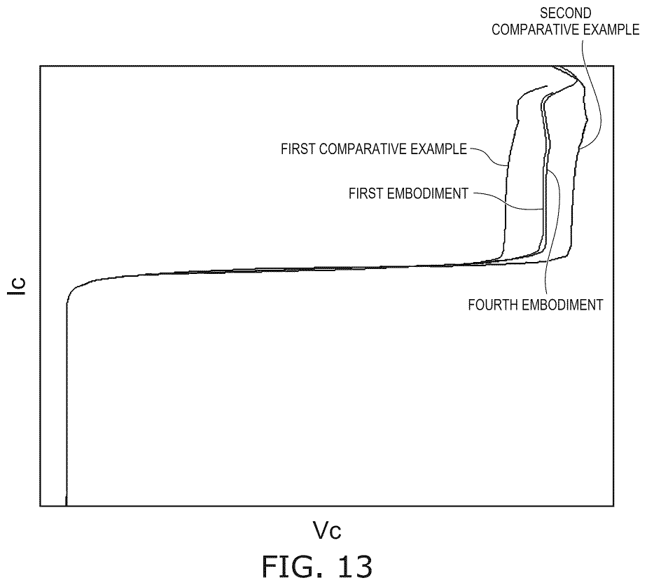

FIG. 13 shows I-V characteristic simulation results of the semiconductor devices of the first embodiment shown in FIG. 2, the fourth embodiment shown in FIG. 5, a first comparative example, and a second comparative example. The horizontal axis is a collector-emitter voltage Vc. The vertical axis is a collector current Ic.

In the first comparative example and the second comparative example, an n-type buffer layer of a uniform thickness was located in the active region 100 and the termination region 200. In the first comparative example and the second comparative example, the configurations other than the n-type buffer layer were the same as those of the semiconductor device 1 according to the first embodiment.

In the first comparative example, a thick n-type buffer layer (the first part 13A of the third semiconductor layer 13 according to the embodiment) was located in the active region 100 and the termination region 200.

In the second comparative example, a thin n-type buffer layer (the second part 13B of the third semiconductor layer 13 according to the embodiment) was located in the active region 100 and the termination region 200.

The second comparative example in which a thin buffer layer extended over the entire region had the highest voltage at which the avalanche current occurred, i.e., the highest breakdown voltage. In the second comparative example, the difference between the voltage at which the avalanche current occurred and the voltage of the switch to the negative resistance region was small. In the second comparative example, the buffer layer was thin, and so oscillations of the collector current and the collector-emitter voltage at turn-off occurred easily.

For the first comparative example in which a thick buffer layer extended over the entire region, the calculation did not converge due to an abrupt switch to the negative resistance region; and a portion of the negative resistance region is not illustrated. For the first embodiment as well, the calculation did not converge at the switch to the negative resistance region; and a portion of the negative resistance region is not illustrated. The voltage at which the avalanche current occurred was lowest for the first comparative example. The voltage at which the avalanche current occurred according to the first embodiment was higher than that of the first comparative example. According to the fourth embodiment, even when a thick buffer layer was formed, the voltage of the switch to the negative resistance region was about as high as that of the second comparative example.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a first electrode;
a second electrode; and
a semiconductor part positioned between the first electrode and the second electrode in a first direction, the semiconductor part including
an active region,
a side surface, and
a termination region positioned between the active region and the side surface in a direction crossing the first direction,
the semiconductor part including
a first semiconductor layer of a first conductivity type,
a second semiconductor layer positioned between the first electrode and the first semiconductor layer in the first direction in at least the active region, the second semiconductor layer being electrically connected with the first electrode,
a third semiconductor layer positioned between the first electrode and the first semiconductor layer in the first direction, the third semiconductor layer being of the first conductivity type and having a higher first-conductivity-type impurity concentration than the first semiconductor layer,
a fourth semiconductor layer positioned between the second electrode and the first semiconductor layer in the first direction in the active region, the fourth semiconductor layer being electrically connected with the second electrode, the fourth semiconductor layer being of a second conductivity type, and
a fifth semiconductor layer positioned between the second electrode and the first semiconductor layer in the first direction in the termination region, the fifth semiconductor layer being positioned between the fourth semiconductor layer and the side surface in the direction crossing the first direction, the fifth semiconductor layer being of the second conductivity type,
the third semiconductor layer including
a first part positioned in the active region, the first part facing at least a part of the fifth semiconductor layer in the first direction, and
a second part positioned between the first part and the side surface in the direction crossing the first direction, the second part being thinner than the first part.

2. The device according to claim 1, wherein
the fifth semiconductor layer includes:
a third part facing the first part of the third semiconductor layer in the first direction; and
a fourth part positioned between the third part and the side surface in the direction crossing the first direction, the fourth part facing the first part of the third semiconductor layer in the first direction, and
a distance in the first direction between the first part of the third semiconductor layer and the fourth part of the fifth semiconductor layer is less than a distance in the first direction between the first part of the third semiconductor layer and the third part of the fifth semiconductor layer.

3. The device according to claim 2, wherein
the distance in the first direction between the third part of the fifth semiconductor layer and the first part of the third semiconductor layer is less than a distance in the first direction between the fourth semiconductor layer and the first part of the third semiconductor layer.

4. The device according to claim 3, wherein
the fourth part of the fifth semiconductor layer is deeper than the third part of the fifth semiconductor layer with respect to a surface of the semiconductor part at the second electrode side.

5. The device according to claim 1, wherein
a distance in the first direction between the fifth semiconductor layer and the first part of the third semiconductor layer gradually decreases from the active region side toward the side surface.

6. The device according to claim 2, wherein
the fifth semiconductor layer includes a fifth part separated from the fourth part at the side surface side of the fourth part.

7. The device according to claim 6, wherein
the distance in the first direction between the fourth part of the fifth semiconductor layer and the third semiconductor layer is less than a distance in the first direction between the fifth part of the fifth semiconductor layer and the third semiconductor layer.

8. The device according to claim 6, wherein
a boundary between the first part and the second part of the third semiconductor layer is positioned between the fourth part and the fifth part.

9. The device according to claim 1, further comprising:
a gate electrode facing the fourth semiconductor layer in the active region,
the semiconductor part further including a sixth semiconductor layer electrically connected with the second electrode, the sixth semiconductor layer being of the first conductivity type,
the second semiconductor layer being of the second conductivity type.

10. The device according to claim 1, wherein
the second semiconductor layer is of the first conductivity type and has a higher first-conductivity-type impurity concentration than the first semiconductor layer.

11. The device according to claim 1, wherein
the second semiconductor layer is continuous in the active region and the termination region.

12. The device according to claim 2, wherein
the distance in the first direction between the third part of the fifth semiconductor layer and the first part of the third semiconductor layer is equal to the distance in the first direction between the fourth semiconductor layer and the first part of the third semiconductor layer.

13. The device according to claim 1, wherein
an end portion of the first part of the third semiconductor layer at the second part side has a greater thickness in the first direction than a portion of the first part of the third semiconductor layer at the active region side.

14. The device according to claim 1, wherein
a thickness in the first direction of an end portion of the first part of the third semiconductor layer at the second part side gradually increases from the active region side toward the side surface of the semiconductor part.

15. The device according to claim 2, wherein
the fifth semiconductor layer includes a fifth part positioned at the side surface side of the fourth part, and
the distance in the first direction between the fourth part of the fifth semiconductor layer and the third semiconductor layer is less than a distance in the first direction between the fifth part of the fifth semiconductor layer and the third semiconductor layer.

16. The device according to claim 15, wherein
the fourth part and the fifth part are continuous in the direction crossing the first direction.

17. The device according to claim 1, further comprising:
a first field plate electrically connected with the fifth semiconductor layer,
the fifth semiconductor layer being positioned between the first semiconductor layer and the first field plate in the first direction,
an end of the first field plate proximate to the side surface being positioned more proximate to the side surface than an end of the fifth semiconductor layer proximate to the side surface.

18. The device according to claim 17, wherein
the end of the first field plate proximate to the side surface is positioned more proximate to the side surface than a boundary between the first part and the second part of the third semiconductor layer.

19. The device according to claim 6, further comprising:
a first field plate electrically connected with the fifth semiconductor layer,
the first field plate including
a first region positioned above the fourth part, and
a second region positioned above the fifth part,
the first region and the second region being separated from each other.

20. The device according to claim 1, wherein
the third semiconductor layer contacts the first electrode in the termination region.
